(19) United States
(12) Patent Application Publication
(10) Pub. No.: US 2026/0068276 A1
(43) Pub. Date: Mar. 5, 2026

(54) SEMICONDUCTOR DEVICE

(71) Applicant: Mitsubishi Electric Corporation, Tokyo (JP)

(72) Inventors: Kazuya KONISHI, Tokyo (JP); Kosuke SAKAGUCHI, Tokyo (JP); Ryosuke KOBAYASHI, Tokyo (JP); Kazuki NISHIDA, Tokyo (JP); Kakeru OTSUKA, Tokyo (JP); Fumihito MASUOKA, Tokyo (JP); Masanori TSUKUDA, Tokyo (JP); Shinya SONEDA, Tokyo (JP)

(73) Assignee: Mitsubishi Electric Corporation, Tokyo (JP)

(21) Appl. No.: 19/261,706

(22) Filed: Jul. 7, 2025

(30) Foreign Application Priority Data
Aug. 30, 2024 (JP) 2024-148230

(51) Int. Cl. H10D 64/27; H10D 12/00; H10D 64/00; H10D 84/00

(52) U.S. Cl. CPC H10D 64/518; H10D 12/481; H10D 64/112; H10D 64/117; H10D 64/513; H10D 64/516; H10D 84/161

(57) ABSTRACT

A semiconductor device according to the present disclosure is an insulated gate bipolar transistor (IGBT) including: a semiconductor substrate; a two-stage active trench having an upper electrode connected to a gate electrode and covered with an upper insulating film in an upper stage, a lower electrode connected to the gate electrode and covered with a lower insulating film in a lower stage, and a boundary insulating film located between the upper electrode and the lower electrode inside a trench provided on a front surface side of the semiconductor substrate; and a dummy trench having a dummy electrode covered with a dummy insulating film inside a trench provided on the front surface side of the semiconductor substrate, wherein a film thickness of the lower insulating film and a film thickness of the dummy insulating film are thicker than a film thickness of the upper insulating film.

### BACKGROUND OF THE INVENTION

### Field of the Invention

The present disclosure relates to a semiconductor device whose conduction is controlled by a gate signal.

### Description of the Background Art

Conventionally, there is disclosed a semiconductor device including a gate trench and a dummy trench.

In a case where the semiconductor device is an insulated gate bipolar transistor (IGBT), an electric field concentrates at a bottom of a trench and a dynamic avalanche occurs when the IGBT is turned off or at the time of recovery of a diode. Holes generated by impact ionization by the dynamic avalanche damage an insulating film provided on an inner wall of the trench. As a result, the insulating film is degraded, leading to a decrease in reliability of the semiconductor device, such as breakdown of the insulating film and fluctuation of gate characteristics.

Conventionally, the above-described dynamic avalanche is not sufficiently considered, and thus there is a possibility that the insulating film is degraded.

### SUMMARY

The present disclosure has been made to solve such a problem, and an object thereof is to provide a semiconductor device capable of reducing degradation of an insulating film due to a dynamic avalanche.

In order to solve the above problem, a semiconductor device according to the present disclosure is an insulated gate bipolar transistor (IGBT) including: a semiconductor substrate; a two-stage active trench having an upper electrode connected to a gate electrode and covered with an upper insulating film in an upper stage, a lower electrode connected to the gate electrode and covered with a lower insulating film in a lower stage, and a boundary insulating film located between the upper electrode and the lower electrode inside a trench provided on a front surface side of the semiconductor substrate; a dummy trench having a dummy electrode covered with a dummy insulating film inside a trench provided on the front surface side of the semiconductor substrate; and a collector layer provided on a back surface side of the semiconductor substrate, wherein a film thickness of the lower insulating film and a film thickness of the dummy insulating film are thicker than a film thickness of the upper insulating film.

According to the present disclosure, it is possible to reduce the degradation of the insulating film due to the dynamic avalanche.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a cross-sectional view of a semiconductor device according to a first preferred embodiment;

FIG. 2 is a cross-sectional view of a semiconductor device according to a first modification of the first preferred embodiment;

FIG. 3 is a cross-sectional view of a semiconductor device according to a second modification of the first preferred embodiment;

FIGS. 4 to 6 are each a cross-sectional view of a semiconductor device according to a third modification of the first preferred embodiment;

FIG. 7 is a cross-sectional view of a semiconductor device according to a fourth modification of the first preferred embodiment;

FIG. 8 is a cross-sectional view of a semiconductor device according to a fifth modification of the first preferred embodiment;

FIG. 9 is a cross-sectional view of a semiconductor device according to a sixth modification of the first preferred embodiment;

FIGS. 10 and 11 are each a plan view of a semiconductor device according to a seventh modification of the first preferred embodiment;

FIGS. 12 to 14 are each a cross-sectional view of a semiconductor device according to an eighth modification of the first preferred embodiment;

FIG. 15 is a cross-sectional view of a semiconductor device according to a ninth modification of the first preferred embodiment;

FIG. 16 is a cross-sectional view of a semiconductor device according to a tenth modification of the first preferred embodiment;

FIG. 17 is a cross-sectional view of a semiconductor device according to an eleventh modification of the first preferred embodiment;

FIG. 18 is a cross-sectional view of a semiconductor device according to a twelfth modification of the first preferred embodiment;

FIGS. 19 and 20 are each a cross-sectional view of a semiconductor device according to a thirteenth modification of the first preferred embodiment;

FIG. 21 is a cross-sectional view of a semiconductor device according to a fourteenth modification of the first preferred embodiment; and

FIG. 22 is a cross-sectional view of a semiconductor device according to a second preferred embodiment.

### DESCRIPTION OF THE PREFERRED EMBODIMENTS

### First Preferred Embodiment

Hereinafter, semiconductor devices according to preferred embodiments will be described with reference to the drawings. The semiconductor device is an IGBT. Note that the same or corresponding components are denoted by the same reference signs, and repetition of the description may be omitted. In the following description, N and P represent conductivity types of a semiconductor. These conductivity types may be reversed.

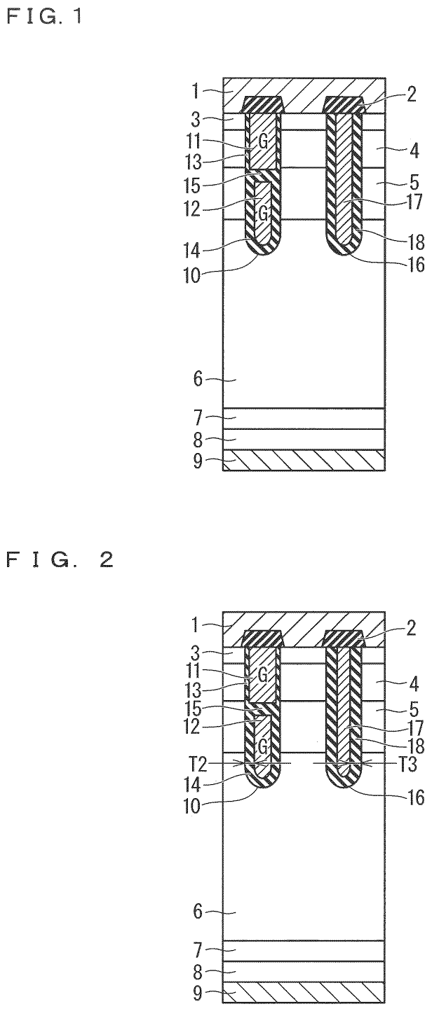

FIG. 1 is a cross-sectional view of the semiconductor device according to the first preferred embodiment. In FIG. 1, the semiconductor substrate ranges from a source layer 3 to a collector layer 8. In FIG. 1, an upper end of the source layer 3 is referred to as a front surface of the semiconductor substrate, and a lower end of the collector layer 8 is referred to as a back surface of the semiconductor substrate. The front surface and the back surface face each other.

As illustrated in FIG. 1, a carrier accumulation layer 5 of the N type having an N-type impurity concentration higher than that of a drift layer 6 of the N type is provided on the front surface side of the drift layer 6. Note that the semiconductor device may have a configuration in which the carrier accumulation layer 5 is not provided. In this case, the drift layer 6 is also provided in a region of the carrier accumulation layer 5 illustrated in FIG. 1.

A base layer 4 of the P type is provided on the front surface side of the carrier accumulation layer 5. A source layer 3 of the N type is provided on the front surface side of the base layer 4.

A two-stage active trench 10 that penetrates the source layer 3, the base layer 4, and the carrier accumulation layer 5 and reaches the drift layer 6 is provided in the semiconductor substrate. The two-stage active trench 10 has an upper electrode 11 connected to a gate electrode (not illustrated) in an upper stage and a lower electrode 12 connected to the gate electrode in a lower stage inside a trench provided on the front surface side of the semiconductor substrate. The upper electrode 11 is covered with an upper insulating film 13, and the lower electrode 12 is covered with a lower insulating film 14. In addition, the two-stage active trench 10 has a boundary insulating film 15 between the upper electrode 11 and the lower electrode 12. The upper electrode 11 and the lower electrode 12 are electrically separated with the boundary insulating film 15 interposed therebetween.

A dummy trench 16 that penetrates the source layer 3, the base layer 4, and the carrier accumulation layer 5 and reaches the drift layer 6 is provided in the semiconductor substrate. The dummy trench 16 has a dummy electrode 17 inside a trench provided on the front surface side of the semiconductor substrate. The dummy electrode 17 is covered with a dummy insulating film 18.

In the two-stage active trench 10 and the dummy trench 16, a film thickness of the lower insulating film 14 and a film thickness of the dummy insulating film 18 are thicker than a film thickness of the upper insulating film 13. Specifically, the film thickness of the lower insulating film 14 and the film thickness of the dummy insulating film 18 are desirably 1.5 times or more the film thickness of the upper insulating film 13, and more desirably twice or more the film thickness of the upper insulating film 13.

An interlayer insulating film 2 is provided on the two-stage active trench 10 and the dummy trench 16. An emitter electrode 1 is provided on the source layer 3 and the interlayer insulating film 2.

A buffer layer 7 of the N type having an N-type impurity concentration higher than that of the drift layer 6 is provided on the back surface side of the drift layer 6. Note that the semiconductor device may have a configuration in which the buffer layer 7 is not provided. In this case, the drift layer 6 is also provided in a region of the buffer layer 7 illustrated in FIG. 1.

The collector layer 8 of the P type is provided on the back surface side of the buffer layer 7. A collector electrode 9 is provided on the back surface side of the collector layer 8.

According to the first preferred embodiment, the film thickness of the lower insulating film 14 and the film thickness of the dummy insulating film 18 are thicker than the film thickness of the upper insulating film 13 in the two-stage active trench 10 and the dummy trench 16. Since the film thickness of the lower insulating film 14 and the film thickness of the dummy insulating film 18 are made thick, it is possible to reduce degradation of an insulating film due to a dynamic avalanche in a wide range and to suppress a decrease in reliability of the semiconductor device. In addition, since the film thickness of the upper insulating film 13 is not thick, low channel resistance can be maintained.

### First Modification

FIG. 2 is a cross-sectional view of a semiconductor device according to a first modification of the first preferred embodiment. As illustrated in FIG. 2, in the semiconductor device according to the first modification, a film thickness T3 of the dummy insulating film 18 is thicker than a film thickness T2 of the lower insulating film 14.

According to the first modification, since the film thickness of the dummy insulating film 18 capable of reducing the degradation of the insulating film in a wide range is made thicker than the film thickness of the lower insulating film 14, it is possible to suppress fluctuation of characteristics of the semiconductor device due to the degradation of the insulating film.

### Second Modification

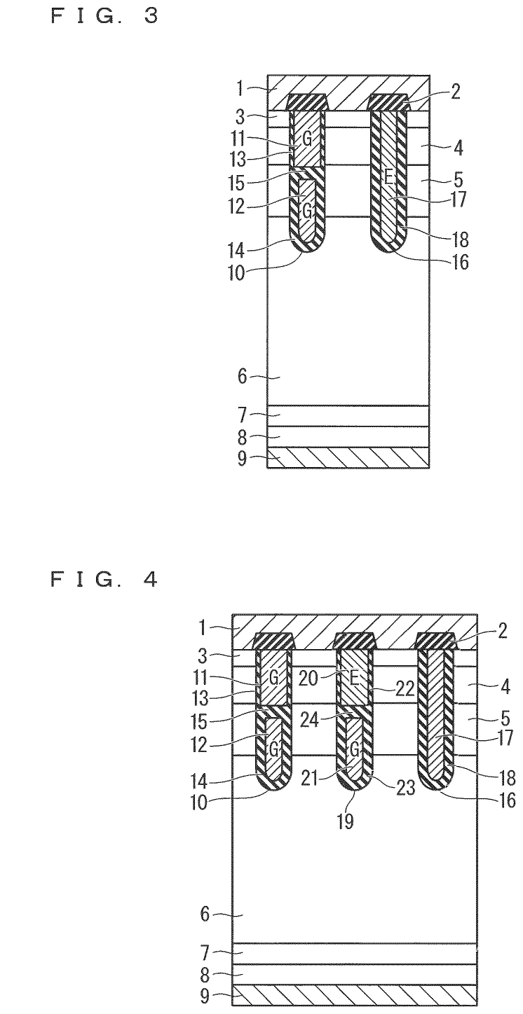

FIG. 3 is a cross-sectional view of a semiconductor device according to a second modification of the first preferred embodiment. As illustrated in FIG. 3, in the semiconductor device according to the second modification, the dummy electrode 17 is electrically connected to the emitter electrode 1.

According to the second modification, since a potential of the dummy electrode 17 in the dummy trench 16 capable of reducing the degradation of the insulating film in a wide range is set to an emitter potential, it is possible to suppress fluctuation of gate characteristics accompanying the degradation of the insulating film.

### Third Modification

FIG. 4 is a cross-sectional view of a semiconductor device according to a third modification of the first preferred embodiment. As illustrated in FIG. 4, the semiconductor device according to the third modification further includes a two-stage dummy active trench 19 that penetrates the source layer 3, the base layer 4, and the carrier accumulation layer 5 and reaches the drift layer 6.

The two-stage dummy active trench 19 has an upper electrode 20 connected to the emitter electrode 1 in an upper stage and a lower electrode 21 connected to the gate electrode in a lower stage inside a trench provided on the front surface side of the semiconductor substrate. The upper electrode 20 is covered with an upper insulating film 22, and the lower electrode 21 is covered with a lower insulating film 23. The two-stage dummy active trench 19 has a boundary insulating film 24 between the upper electrode 20 and the lower electrode 21. The upper electrode 20 and the lower electrode 21 are electrically separated with the boundary insulating film 24 interposed therebetween.

Since a channel is cut off more quickly as a CR time constant, which is the product of gate resistance and a gate capacitance, decreases, the density of electrons decreases, space charge increases, and an electric field increases. Therefore, the degradation of the insulating film due to the dynamic avalanche is promoted. According to the third modification, since the two-stage dummy active trench 19 capable of increasing a gate-collector capacitance is provided, the CR time constant increases, and the influence of the dynamic avalanche can be reduced, so that the degradation of the insulating film can be reduced.

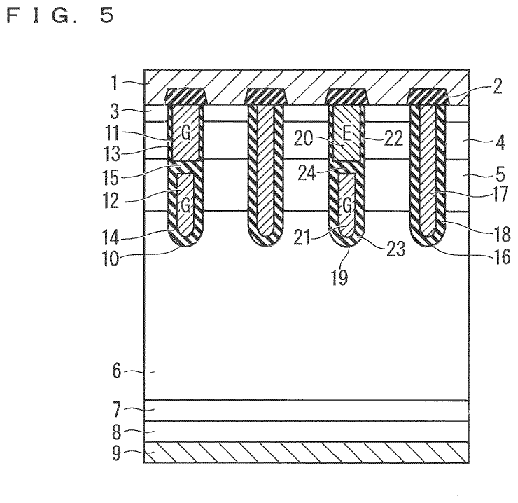

Although the two-stage dummy active trench 19 is provided between the two-stage active trench 10 and the dummy trench 16 in the example of FIG. 4, the location where the two-stage dummy active trench 19 is arranged is not limited thereto. For example, the two-stage dummy active trench 19 may be provided between the dummy trenches 16 as illustrated in FIG. 5. With the configuration illustrated in FIG. 5, holes can be discharged without uneven hole distribution in the lateral direction by the dummy trenches 16, so that the occurrence of the dynamic avalanche can be reduced.

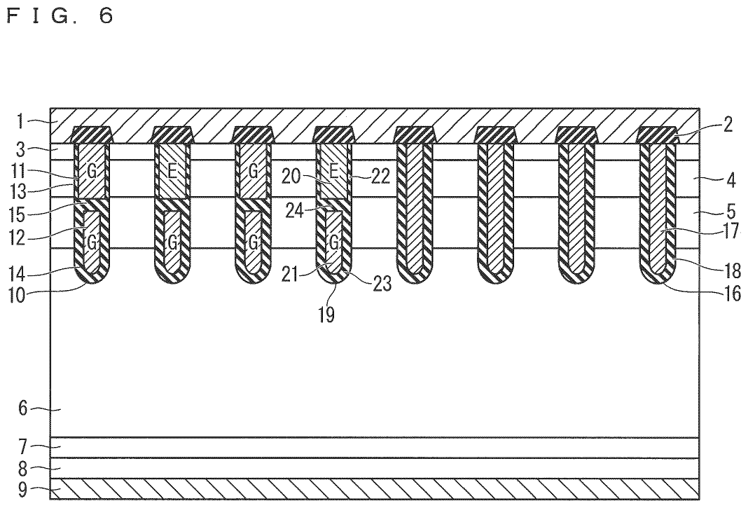

In addition, the two-stage dummy active trench 19 may be provided between the two-stage active trenches 10 as illustrated in FIG. 6. When the two-stage dummy active trench 19 and the dummy trench 16 are arranged so as to be adjacent to each other, Cge (capacitance between the gate electrode and the emitter electrode) is generated between the dummy electrode 17 (here, the dummy electrode 17 is assumed to be connected to the emitter electrode 1) and the lower electrode 21 connected to the gate electrode, which face each other in the lateral direction, leading to an increase in switching loss. With the configuration illustrated in FIG. 6, Cge can be reduced, so that the switching loss can be reduced.

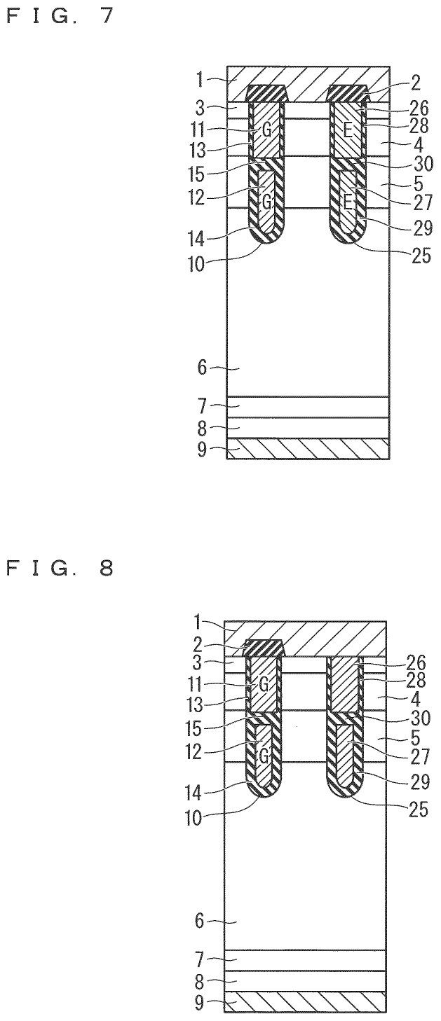

In FIGS. 4 to 6, a two-stage dummy trench 25 illustrated in FIG. 7 to be described later may be provided instead of the dummy trench 16. In this case, an upper dummy electrode 26 and a lower dummy electrode 27 in the two-stage dummy trench 25 may be connected to the emitter electrode 1 or unconnected to the emitter electrode 1.

### Fourth Modification

FIG. 7 is a cross-sectional view of a semiconductor device according to a fourth modification of the first preferred embodiment. As illustrated in FIG. 7, the semiconductor device according to the fourth modification includes the two-stage dummy trench 25 obtained by dividing the dummy electrode 17 illustrated in FIG. 1 into two parts in an upper stage and a lower stage.

The two-stage dummy trench 25 has the upper dummy electrode 26 connected to the emitter electrode 1 in the upper stage and the lower dummy electrode 27 connected to the emitter electrode 1 in the lower stage. The upper dummy electrode 26 is covered with an upper dummy insulating film 28, and the lower dummy electrode 27 is covered with a lower dummy insulating film 29. The upper dummy electrode 26 and the lower dummy electrode 27 are electrically separated with a boundary insulating film 30 interposed therebetween.

In addition, in the two-stage dummy trench 25, a film thickness of the upper dummy insulating film 28 is thinner than a film thickness of the lower dummy insulating film 29.

According to the fourth modification, since the two-stage dummy trench 25 having the upper dummy electrode 26 and the lower dummy electrode 27, which are connected to the emitter electrode 1, is provided, holes are attracted to the emitter potential, so that the density of holes at an interface of the two-stage dummy trench 25 increases, and a hole discharge path with low resistance is formed at the interface of the two-stage dummy trench 25.

In particular, since the thickness of the upper dummy insulating film 28 is made thinner, the hole attraction effect is further enhanced, so that the hole discharge path with lower resistance can be formed. Therefore, the amount of holes injected into the insulating film can be reduced by quickly discharging the holes generated by the dynamic avalanche to the emitter electrode 1 via the discharge path, so that the degradation of the insulating film can be reduced.

### Fifth Modification

FIG. 8 is a cross-sectional view of a semiconductor device according to a fifth modification of the first preferred embodiment. As illustrated in FIG. 8, the interlayer insulating film 2 is not provided on the upper dummy electrode 26 in the semiconductor device according to the fifth modification.

According to the fifth modification, since the interlayer insulating film 2 is not provided on the upper dummy electrode 26, a contact width on the front surface of the semiconductor substrate is widened to enlarge the hole discharge path, and the hole discharge effect can be promoted. Therefore, the degradation of the insulating film can be suppressed.

In FIG. 8, the upper dummy electrode 26 and the lower dummy electrode 27 may be connected to the emitter electrode 1 as in the fourth modification.

In FIG. 8, the dummy trench 16 illustrated in FIG. 1 may be provided instead of the two-stage dummy trench 25. In this case, the semiconductor device has a configuration in which the interlayer insulating film 2 is not provided on the dummy electrode 17.

### Sixth Modification

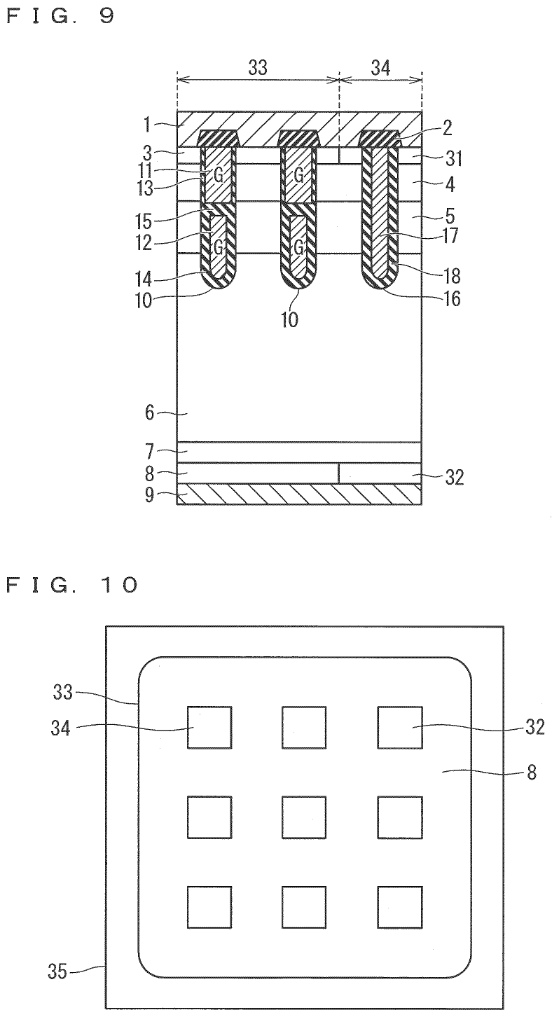

FIG. 9 is a cross-sectional view of a semiconductor device according to a sixth modification of the first preferred embodiment. As illustrated in FIG. 9, the semiconductor device according to the sixth modification is an RC-IGBT having an IGBT region 33 and a diode region 34.

The IGBT region 33 has a configuration similar to the configuration described in the first preferred embodiment (see FIG. 1). In the IGBT region 33, two two-stage active trenches 10 are provided. Although the two two-stage active trenches 10 are provided in the example of FIG. 9, a plurality of (for example, several tens to several hundreds of) the two-stage active trenches 10 may be provided.

In the diode region 34, an anode layer 31 is provided so as to be adjacent to the source layer 3 of the IGBT region 33, and a cathode layer 32 is provided so as to be adjacent to the collector layer 8 of the IGBT region 33. The dummy trench 16 is provided in the diode region 34. Although one dummy trench 16 is provided in the example of FIG. 9, a plurality of the dummy trenches 16 may be provided.

In the RC-IGBT, the diode region is designed to be smaller than the IGBT region in order to reduce a chip size. Therefore, the current density of the diode increases, and the insulating film is easily damaged by the dynamic avalanche. According to the sixth modification, the degradation of the insulating film can be reduced by providing the dummy trench 16 in the diode region 34 greatly affected by the dynamic avalanche.

In FIG. 9, the two-stage dummy trench 25 illustrated in FIG. 7 may be provided instead of the dummy trench 16. In this case, an upper dummy electrode 26 and a lower dummy electrode 27 in the two-stage dummy trench 25 may be connected to the emitter electrode 1 or unconnected to the emitter electrode 1.

### Seventh Modification

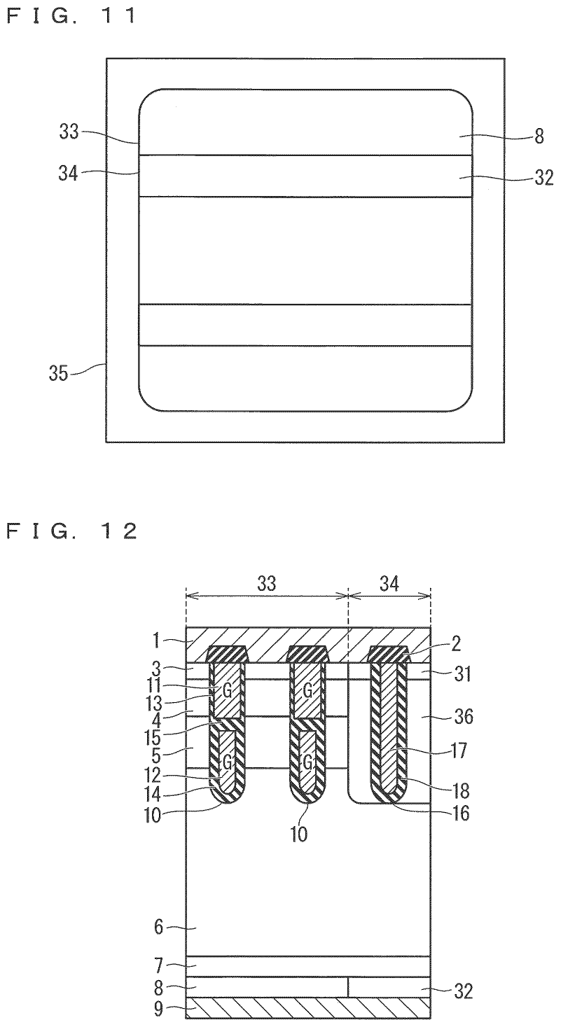

FIGS. 10 and 11 are plan views of a semiconductor device according to a seventh modification of the first preferred embodiment. FIG. 10 illustrates an example in which the diode regions 34 are arranged in islands, and FIG. 11 illustrates an example in which the diode regions 34 are arranged in stripes. Configurations of the IGBT region 33 and the diode region 34 in FIGS. 10 and 11 are similar to those in the sixth modification.

As illustrated in FIGS. 10 and 11, in the semiconductor device according to the seventh modification, the area of the diode region 34 is smaller than the area of the IGBT region 33 in plan view.

When the area of the diode region 34 is made smaller, the current density of the diode increases, so that the influence of the dynamic avalanche on the diode region 34 increases. According to the seventh modification, it is possible to effectively reduce the degradation of the insulating film by providing the dummy trench 16 or the two-stage dummy trench 25 in the diode region 34 greatly affected by the dynamic avalanche.

When the area of the diode region 34 is set to half or less of the area of the IGBT region 33, the current density of the diode becomes twice the current density of the IGBT, so that the effect of reducing the degradation of the insulating film is further enhanced as compared with a case where the area of the diode region 34 is the same as the area of the IGBT region 33.

The arrangement of the diode regions 34 is not limited, but the island arrangement illustrated in FIG. 10 is desirable. Since the avalanche is more likely to occur at a lower temperature, the island arrangement in which heat is dispersed to lower the temperature of the semiconductor is highly effective in reducing the degradation of the insulating film.

### Eighth Modification

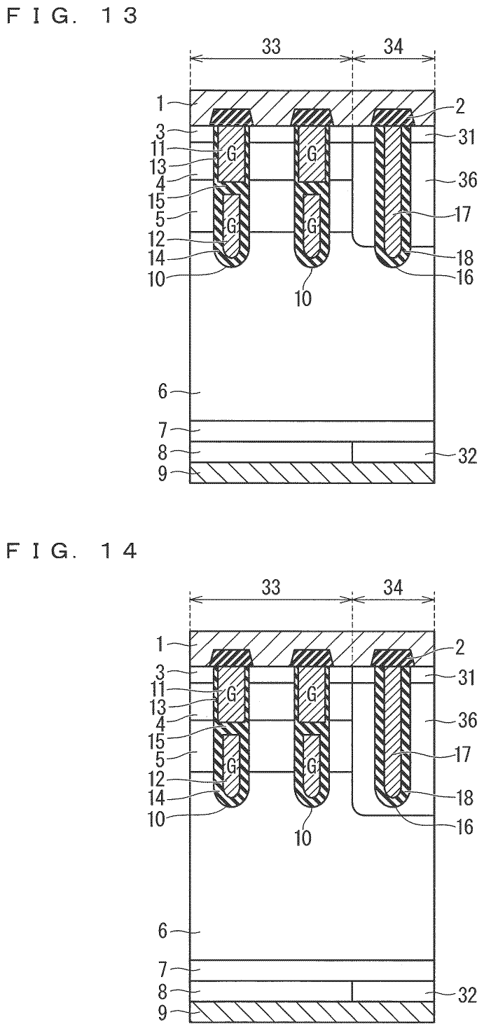

FIG. 12 is a cross-sectional view of a semiconductor device according to an eighth modification of the first preferred embodiment. As illustrated in FIG. 12, the semiconductor device according to the eighth modification includes a second anode layer 36 in the diode region 34. Configurations of the IGBT region 33 and the diode region 34 in FIG. 12 are similar to those in the sixth modification except for the second anode layer 36.

The second anode layer 36 is provided on the back surface side of the anode layer 31. An impurity concentration of the anode layer 31 is higher than an impurity concentration of the second anode layer 36.

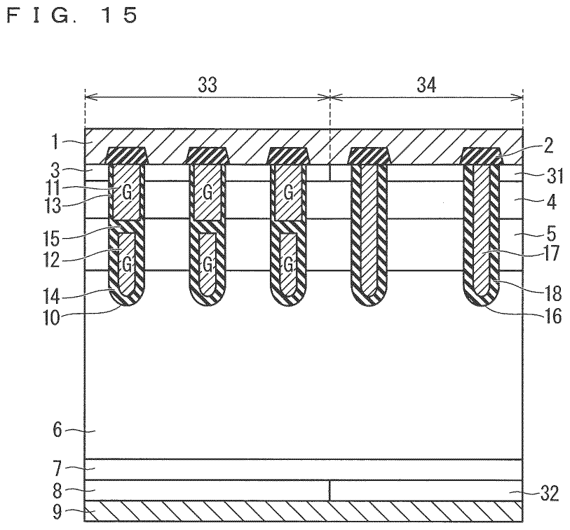

A depth of the second anode layer 36 is deeper than a depth of the base layer 4. Although the depth of the second anode layer 36 and a depth of the dummy trench 16 are the same in the example of FIG. 12, the present disclosure is not limited thereto. The depth of the second anode layer 36 only needs to be deeper than the depth of the base layer 4, and is desirably deeper than the carrier accumulation layer 5 (see FIG. 13) and more desirably the same as the depth of the dummy trench 16, or may be deeper than the depth of the dummy trench 16 (see FIG. 14).

According to the eighth modification, since the depth of the second anode layer 36 is made deeper than the depth of the base layer 4, an electric field at a bottom of the two-stage active trench 10 can be further reduced by an electric field relaxation effect obtained by the second anode layer 36. In addition, since the impurity concentration of the second anode layer 36 is set to be lower than the impurity concentration of the base layer 4, the electric field can be further reduced.

### Ninth Modification

FIG. 15 is a cross-sectional view of a semiconductor device according to a ninth modification of the first preferred embodiment. As illustrated in FIG. 15, in the semiconductor device according to the ninth modification, an interval at which the dummy trenches 16 are arranged in the diode region 34 is wider than an interval at which the two-stage active trenches 10 are arranged in the IGBT region 33. Configurations of the IGBT region 33 and the diode region 34 are similar to those in the sixth modification. In addition, the configuration of the diode region 34 may be combined with the configuration in the eighth modification.

According to the ninth modification, since the interval at which the dummy trenches 16 are arranged in the diode region 34 is made wider than the interval at which the two-stage active trenches 10 are arranged in the IGBT region 33, a mesa width sandwiched between the dummy trenches 16 is widened, and the hole discharge path is enlarged. Therefore, the holes generated by dynamic avalanche can be discharged from the emitter electrode 1, and the degradation of the insulating film can be reduced.

### Tenth Modification

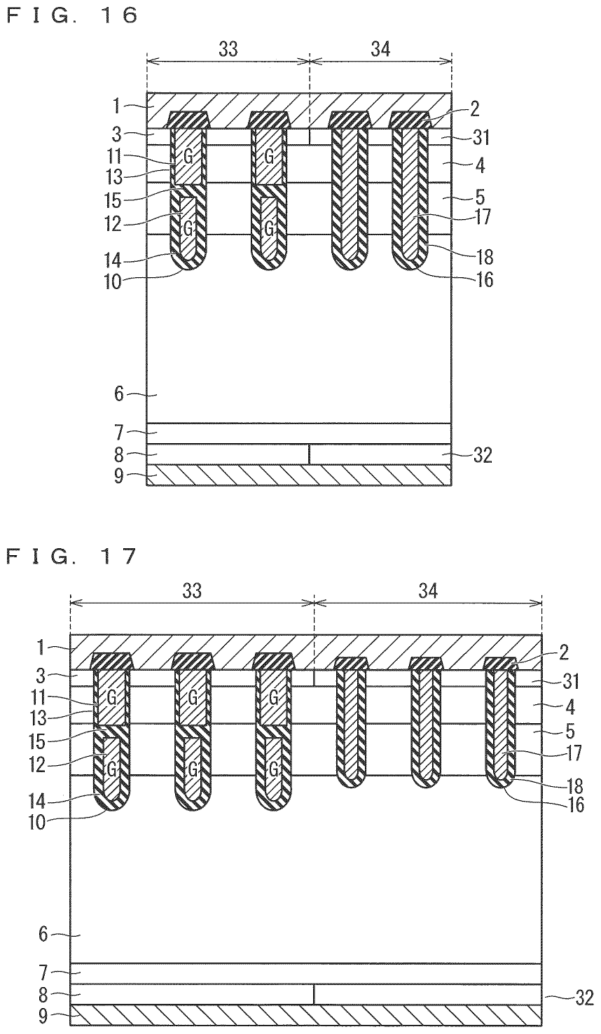

FIG. 16 is a cross-sectional view of a semiconductor device according to a tenth modification of the first preferred embodiment. As illustrated in FIG. 16, in the semiconductor device according to the tenth modification, the interval at which the dummy trenches 16 are arranged in the diode region 34 is narrower than the interval at which the two-stage active trenches 10 are arranged in the IGBT region 33. Configurations of the IGBT region 33 and the diode region 34 in FIG. 16 are similar to those in the sixth modification. In addition, the configuration of the diode region 34 may be combined with the configuration in the eighth modification.

According to a tenth modification, since the interval at which the dummy trenches 16 are arranged in the diode region 34 is made narrower than the interval at which the two-stage active trenches 10 are arranged in the IGBT region 33, the electric field relaxation effect can be enhanced by the dummy trenches 16. Therefore, since the influence of the dynamic avalanche can be reduced by reducing the electric field, the degradation of the insulating film can be reduced.

### Eleventh Modification

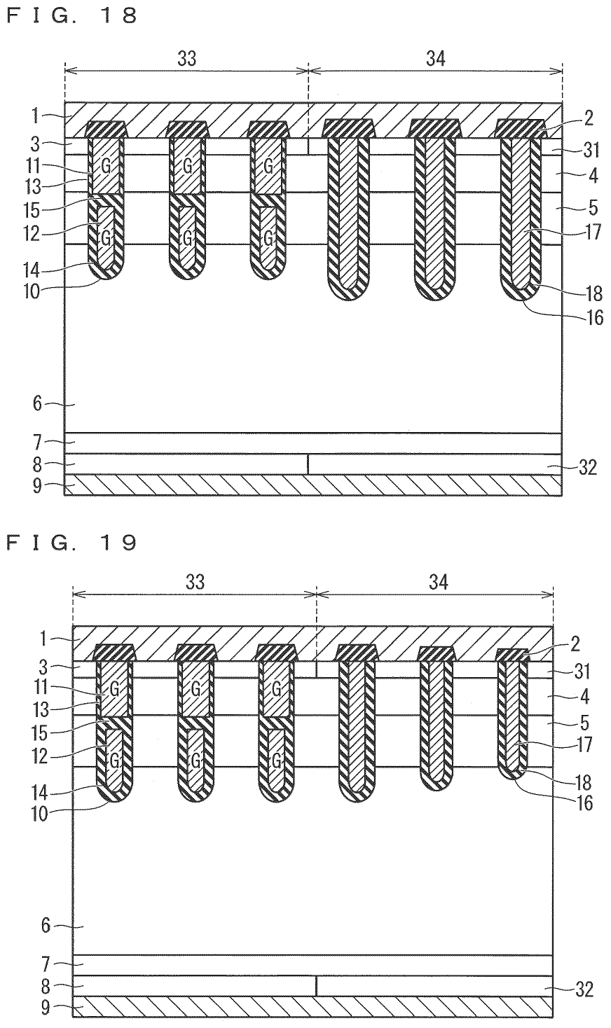

FIG. 17 is a cross-sectional view of a semiconductor device according to an eleventh modification of the first preferred embodiment. As illustrated in FIG. 17, in the semiconductor device according to the eleventh modification, the depth of the dummy trench 16 in the diode region 34 is shallower than a depth of the two-stage active trench 10 in the IGBT region 33. Configurations of the IGBT region 33 and the diode region 34 are similar to those in the sixth modification. In addition, the configuration of the diode region 34 may be combined with the configuration in the eighth modification.

In order to make the depth of the dummy trench 16 shallower, a width of the dummy trench 16 may be narrower than a width of the two-stage active trench 10. When the width of the dummy trench 16 is made narrower, the depth of the dummy trench 16 can be made shallower than the depth of the two-stage active trench 10 by a micro-loading effect.

According to the eleventh modification, since the depth of the dummy trench 16 in the diode region 34 is made shallower than the depth of the two-stage active trench 10 in the IGBT region 33, the concentration of the electric field to the bottom of the dummy trench 16 can be reduced, and the degradation of the insulating film can be reduced. In addition, since the depth of the dummy trench 16 is made shallower, the electric field is reduced by a depletion layer from the base layer 4 and the anode layer 31, and the degradation of the insulating film can be reduced.

### Twelfth Modification

FIG. 18 is a cross-sectional view of a semiconductor device according to a twelfth modification of the first preferred embodiment. As illustrated in FIG. 18, in the semiconductor device according to the twelfth modification, the depth of the dummy trench 16 in the diode region 34 is deeper than the depth of the two-stage active trench 10 in the IGBT region 33. Configurations of the IGBT region 33 and the diode region 34 are similar to those in the sixth modification. In addition, the configuration of the diode region 34 may be combined with the configuration in the eighth modification.

In order to make the depth of the dummy trench 16 deeper, the width of the dummy trench 16 may be wider than the width of the two-stage active trench 10.

According to the twelfth modification, since the depth of the dummy trench 16 in the diode region 34 is made deeper than the depth of the two-stage active trench 10 in the IGBT region 33, holes are attracted to the dummy trench 16, and the holes can be discharged to the emitter electrode 1 via the dummy trench 16. As a result, the degradation of the insulating film can be reduced.

### Thirteenth Modification

FIG. 19 is a cross-sectional view of a semiconductor device according to a thirteenth modification of the first preferred embodiment. As illustrated in FIG. 19, in the semiconductor device according to the thirteenth modification, the depths of the dummy trenches 16 gradually decrease as the distance from the IGBT region 33 increases.

In an end portion of the diode region 34, the electric field is likely to increase, and the concentration of the electric field occurs when a difference between the depth of the dummy trench 16 and the depth of the two-stage active trench 10 is large. Therefore, since the depths of the dummy trenches 16 gradually decrease, the electric field can be reduced, and the degradation of the insulating film can be reduced.

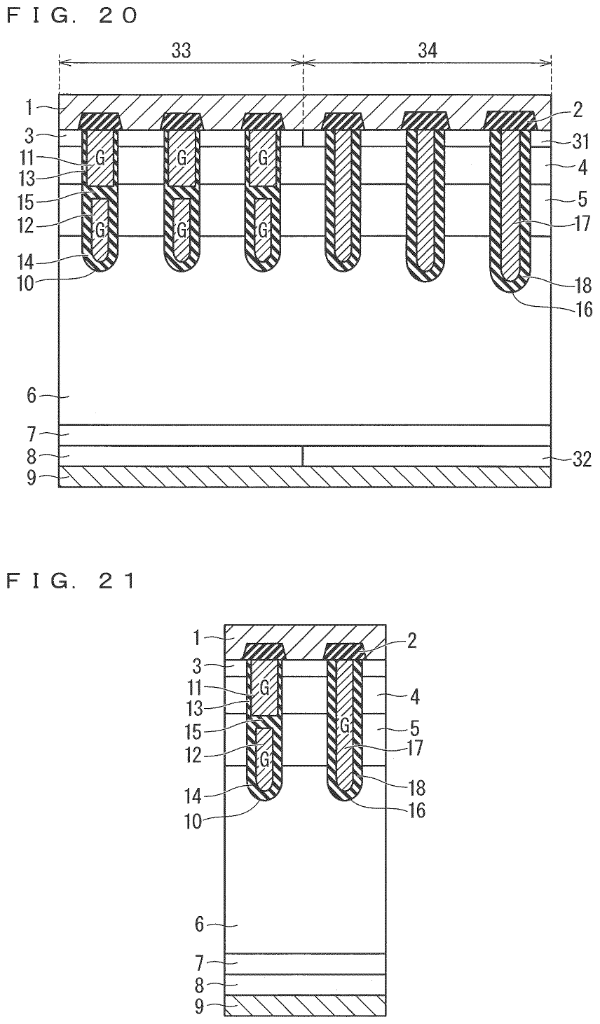

Although FIG. 19 illustrates the configuration in which the depths of the dummy trenches 16 gradually decrease, the present disclosure is not limited thereto. For example, as illustrated in FIG. 20, the depths of the dummy trenches 16 may gradually increase as the distance from the IGBT region 33 increases.

### Fourteenth Modification

FIG. 21 is a cross-sectional view of a semiconductor device according to a fourteenth modification of the first preferred embodiment. As illustrated in FIG. 21, in the semiconductor device according to the fourteenth modification, the dummy electrode 17 is connected to the gate electrode.

According to the fourteenth modification, since the film thickness of the dummy insulating film 18 is thick, it is possible to reduce degradation of the insulating film even when the dummy electrode 17 is set to a gate potential.

Since the channel is cut off more quickly as the CR time constant, which is the product of the gate resistance and the gate capacitance, decreases, the density of electrons decreases, the space charge increases, and the electric field increases. Therefore, the degradation of the insulating film due to the dynamic avalanche is promoted. According to the fourteenth modification, since the dummy electrode 17 is electrically connected to the gate electrode, the CR time constant increases, and the influence of the dynamic avalanche can be reduced, so that the degradation of the insulating film can be reduced.

### Second Preferred Embodiment

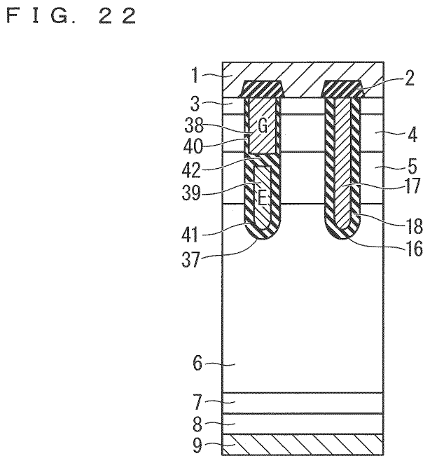

FIG. 22 is a cross-sectional view of a semiconductor device according to a second preferred embodiment. The semiconductor device according to the second preferred embodiment includes a two-stage active dummy trench 37 instead of the two-stage active trench 10 included in the semiconductor device (see FIG. 1) according to the first preferred embodiment. Other configurations are similar to the configurations illustrated in FIG. 1.

The two-stage active dummy trench 37 that penetrates the source layer 3, the base layer 4, and the carrier accumulation layer 5 and reaches the drift layer 6 is provided in a semiconductor substrate. The two-stage active dummy trench 37 has an upper electrode 38 connected to a gate electrode in an upper stage and a lower electrode 39 connected to the emitter electrode 1 in a lower stage inside a trench provided on a front surface side of the semiconductor substrate. The upper electrode 38 is covered with an upper insulating film 40, and the lower electrode 39 is covered with a lower insulating film 41. The two-stage active dummy trench 37 has a boundary insulating film 42 between the upper electrode 38 and the lower electrode 39. The upper electrode 38 and the lower electrode 39 are electrically separated with the boundary insulating film 42 interposed therebetween.

According to the second preferred embodiment, since a potential of the lower electrode 39 in the two-stage active dummy trench 37 is set to an emitter potential, it is possible to suppress fluctuation of gate characteristics accompanying degradation of an insulating film.

Note that the semiconductor device according to the second preferred embodiment may be adapted to the first to fourteenth modifications of the first preferred embodiment. In this case, the two-stage active trench 10 in each the first to fourteenth modifications is replaced with the two-stage active dummy trench 37.

Within the scope of the present disclosure, each of the preferred embodiments can be freely combined, and each of the preferred embodiments can be appropriately modified or omitted.

### APPENDIXES

Hereinafter, various aspects of the present disclosure will be collectively described as appendixes.

### Appendix 1

A semiconductor device that is an insulated gate bipolar transistor (IGBT), the semiconductor device comprising:
a semiconductor substrate;
a two-stage active trench having an upper electrode connected to a gate electrode and covered with an upper insulating film in an upper stage, a lower electrode connected to the gate electrode and covered with a lower insulating film in a lower stage, and a boundary insulating film located between the upper electrode and the lower electrode inside a trench provided on a front surface side of the semiconductor substrate;
a dummy trench having a dummy electrode covered with a dummy insulating film inside a trench provided on the front surface side of the semiconductor substrate; and
a collector layer provided on a back surface side of the semiconductor substrate, wherein
a film thickness of the lower insulating film and a film thickness of the dummy insulating film are thicker than a film thickness of the upper insulating film.

### Appendix 2

A semiconductor device that is an insulated gate bipolar transistor (IGBT), the semiconductor device comprising:
a semiconductor substrate;
a two-stage active dummy trench having an upper electrode connected to a gate electrode and covered with an upper insulating film in an upper stage, a lower electrode connected to an emitter electrode and covered with a lower insulating film in a lower stage, and a boundary insulating film located between the upper electrode and the lower electrode inside a trench provided on a front surface side of the semiconductor substrate;
a dummy trench having a dummy electrode covered with a dummy insulating film inside a trench provided on the front surface side of the semiconductor substrate; and
a collector layer provided on a back surface side of the semiconductor substrate, wherein
a film thickness of the lower insulating film and a film thickness of the dummy insulating film are thicker than a film thickness of the upper insulating film.

### Appendix 3

The semiconductor device according to Appendix 1 or 2, wherein the film thickness of the dummy insulating film is thicker than the film thickness of the lower insulating film.

### Appendix 4

The semiconductor device according to any one of Appendixes 1 to 3, wherein the dummy electrode is electrically connected to an emitter electrode.

### Appendix 5

The semiconductor device according to any one of Appendixes 1 to 4, further comprising a two-stage dummy active trench having an upper electrode connected to an emitter electrode in an upper stage and a lower electrode connected to the gate electrode in a lower stage inside a trench provided on the front surface side of the semiconductor substrate.

### Appendix 6

The semiconductor device according to Appendix 4, wherein
the dummy trench is a two-stage dummy trench having an upper dummy electrode connected to the emitter electrode and covered with an upper dummy insulating film in an upper stage, a lower dummy electrode connected to the emitter electrode and covered with a lower dummy insulating film in a lower stage, and a boundary insulating film located between the upper dummy electrode and the lower dummy electrode, and
a film thickness of the upper dummy insulating film is thinner than a film thickness of the lower dummy insulating film.

### Appendix 7

The semiconductor device according to any one of Appendixes 1 to 6, wherein an interlayer insulating film is not provided on the dummy electrode.

### Appendix 8

The semiconductor device according to Appendix 1, further comprising an IGBT region including the collector layer and a diode region including a cathode layer provided on the back surface side of the semiconductor substrate, wherein
the IGBT region includes at least one of the two-stage active trenches, and
the diode region includes at least one of the dummy trenches.

### Appendix 9

The semiconductor device according to Appendix 2, further comprising an IGBT region including the collector layer and a diode region including a cathode layer provided on the back surface side of the semiconductor substrate, wherein
the IGBT region includes at least one of the two-stage active dummy trenches, and
the diode region includes at least one of the dummy trenches.

### Appendix 10

The semiconductor device according to Appendix 8 or 9, wherein an area of the diode region is smaller than an area of the IGBT region in plan view.

### Appendix 11

The semiconductor device according to any one of Appendixes 8 to 10, wherein
the IGBT region includes a base layer provided on the front surface side of the semiconductor substrate,
the diode region includes an anode layer provided on the front surface side of the semiconductor substrate and a second anode layer provided below the anode layer, and
a depth of the second anode layer is deeper than a depth of the base layer.

### Appendix 12

The semiconductor device according to any one of Appendixes 8, 10, and 11, wherein
the IGBT region includes a plurality of the two-stage active trenches,
the diode region includes a plurality of the dummy trenches, and
an interval at which each of the dummy trenches is arranged is wider than an interval at which each of the two-stage active trenches is arranged.

### Appendix 13

The semiconductor device according to any one of Appendixes 9 to 11, wherein
the IGBT region includes a plurality of the two-stage active dummy trenches,
the diode region includes a plurality of the dummy trenches, and
an interval at which each of the dummy trenches is arranged is wider than an interval at which each of the two-stage active dummy trenches is arranged.

### Appendix 14

The semiconductor device according to any one of Appendixes 8, 10, and 11, wherein
the IGBT region includes a plurality of the two-stage active trenches,
the diode region includes a plurality of the dummy trenches, and
an interval at which each of the dummy trenches is arranged is narrower than an interval at which each of the two-stage active trenches is arranged.

### Appendix 15

The semiconductor device according to any one of Appendixes 9 to 11, wherein
the IGBT region includes a plurality of the two-stage active dummy trenches,
the diode region includes a plurality of the dummy trenches, and
an interval at which each of the dummy trenches is arranged is narrower than an interval at which each of the two-stage active dummy trenches is arranged.

### Appendix 16

The semiconductor device according to any one of Appendixes 8, 10, and 11, wherein a depth of the dummy trench is shallower than a depth of the two-stage active trench.

### Appendix 17

The semiconductor device according to any one of Appendixes 9 to 11, wherein a depth of the dummy trench is shallower than a depth of the two-stage active dummy trench.

### Appendix 18

The semiconductor device according to any one of Appendixes 8, 10, and 11, wherein a depth of the dummy trench is deeper than a depth of the two-stage active trench.

### Appendix 19

The semiconductor device according to any one of Appendixes 9 to 11, wherein a depth of the dummy trench is deeper than a depth of the two-stage active dummy trench.

### Appendix 20

The semiconductor device according to any one of Appendixes 8 to 19, wherein
the diode region includes a plurality of the dummy trenches, and
a depth of each of the dummy trenches gradually changes as a distance from the IGBT region increases.

### Appendix 21

The semiconductor device according to any one of Appendixes 1 to 3 or 5 to 20, wherein the dummy electrode is electrically connected to the gate electrode.

While the disclosure has been shown and described in detail, the foregoing description is in all aspects illustrative and not restrictive. It is therefore understood that numerous modifications and variations can be devised.

What is claimed is:

1. A semiconductor device that is an insulated gate bipolar transistor (IGBT), the semiconductor device comprising:
a semiconductor substrate;
a two-stage active trench having an upper electrode connected to a gate electrode and covered with an upper insulating film in an upper stage, a lower electrode connected to the gate electrode and covered with a lower insulating film in a lower stage, and a boundary insulating film located between the upper electrode and the lower electrode inside a trench provided on a front surface side of the semiconductor substrate;
a dummy trench having a dummy electrode covered with a dummy insulating film inside a trench provided on the front surface side of the semiconductor substrate; and
a collector layer provided on a back surface side of the semiconductor substrate,
wherein
a film thickness of the lower insulating film and a film thickness of the dummy insulating film are thicker than a film thickness of the upper insulating film.

2. A semiconductor device that is an insulated gate bipolar transistor (IGBT), the semiconductor device comprising:
a semiconductor substrate;
a two-stage active dummy trench having an upper electrode connected to a gate electrode and covered with an upper insulating film in an upper stage, a lower electrode connected to an emitter electrode and covered with a lower insulating film in a lower stage, and a boundary insulating film located between the upper electrode and the lower electrode inside a trench provided on a front surface side of the semiconductor substrate;
a dummy trench having a dummy electrode covered with a dummy insulating film inside a trench provided on the front surface side of the semiconductor substrate; and
a collector layer provided on a back surface side of the semiconductor substrate,
wherein
a film thickness of the lower insulating film and a film thickness of the dummy insulating film are thicker than a film thickness of the upper insulating film.

3. The semiconductor device according to claim 1, wherein the film thickness of the dummy insulating film is thicker than the film thickness of the lower insulating film.

4. The semiconductor device according to claim 1, wherein the dummy electrode is electrically connected to an emitter electrode.

5. The semiconductor device according to claim 1, further comprising a two-stage dummy active trench having an upper electrode connected to an emitter electrode in an upper stage and a lower electrode connected to the gate electrode in a lower stage inside a trench provided on the front surface side of the semiconductor substrate.

6. The semiconductor device according to claim 4, wherein
the dummy trench is a two-stage dummy trench having an upper dummy electrode connected to the emitter electrode and covered with an upper dummy insulating film in an upper stage, a lower dummy electrode connected to the emitter electrode and covered with a lower dummy insulating film in a lower stage, and a boundary insulating film located between the upper dummy electrode and the lower dummy electrode, and
a film thickness of the upper dummy insulating film is thinner than a film thickness of the lower dummy insulating film.

7. The semiconductor device according to claim 1, wherein an interlayer insulating film is not provided on the dummy electrode.

8. The semiconductor device according to claim 1, further comprising an IGBT region including the collector layer and a diode region including a cathode layer provided on the back surface side of the semiconductor substrate,
wherein
the IGBT region includes at least one of the two-stage active trenches, and
the diode region includes at least one of the dummy trenches.

9. The semiconductor device according to claim 2, further comprising an IGBT region including the collector layer and a diode region including a cathode layer provided on the back surface side of the semiconductor substrate,
wherein
the IGBT region includes at least one of the two-stage active dummy trenches, and
the diode region includes at least one of the dummy trenches.

10. The semiconductor device according to claim 8, wherein an area of the diode region is smaller than an area of the IGBT region in plan view.

11. The semiconductor device according to claim 8, wherein
the IGBT region includes a base layer provided on the front surface side of the semiconductor substrate,
the diode region includes an anode layer provided on the front surface side of the semiconductor substrate and a second anode layer provided below the anode layer, and
a depth of the second anode layer is deeper than a depth of the base layer.

12. The semiconductor device according to claim 8, wherein
the IGBT region includes a plurality of the two-stage active trenches,
the diode region includes a plurality of the dummy trenches, and
an interval at which each of the dummy trenches is arranged is wider than an interval at which each of the two-stage active trenches is arranged.

13. The semiconductor device according to claim 9, wherein
the IGBT region includes a plurality of the two-stage active dummy trenches,
the diode region includes a plurality of the dummy trenches, and
an interval at which each of the dummy trenches is arranged is wider than an interval at which each of the two-stage active dummy trenches is arranged.

14. The semiconductor device according to claim 8, wherein
the IGBT region includes a plurality of the two-stage active trenches,
the diode region includes a plurality of the dummy trenches, and
an interval at which each of the dummy trenches is arranged is narrower than an interval at which each of the two-stage active trenches is arranged.

15. The semiconductor device according to claim 9, wherein
the IGBT region includes a plurality of the two-stage active dummy trenches,
the diode region includes a plurality of the dummy trenches, and
an interval at which each of the dummy trenches is arranged is narrower than an interval at which each of the two-stage active dummy trenches is arranged.

16. The semiconductor device according to claim 8, wherein a depth of the dummy trench is shallower than a depth of the two-stage active trench.

17. The semiconductor device according to claim 9, wherein a depth of the dummy trench is shallower than a depth of the two-stage active dummy trench.

18. The semiconductor device according to claim 8, wherein a depth of the dummy trench is deeper than a depth of the two-stage active trench.

19. The semiconductor device according to claim 9, wherein a depth of the dummy trench is deeper than a depth of the two-stage active dummy trench.

20. The semiconductor device according to claim 8, wherein
the diode region includes a plurality of the dummy trenches, and
a depth of each of the dummy trenches gradually changes as a distance from the IGBT region increases.

21. The semiconductor device according to claim 1, wherein the dummy electrode is electrically connected to the gate electrode.
